(19) United States
(12) Patent Application Publication
(10) Pub. No.: US 2005/0124105 A1
(43) Pub. Date: Jun. 9, 2005

(54) Semiconductor device and method of manufacturing the same

(76) Inventor: Kei Kanemoto, Suwa (JP)

Correspondence Address: HARNESS, DICKEY & PIERCE, P.L.C., P.O. BOX 828, BLOOMFIELD HILLS, MI, 48303, US

(21) Appl. No.: 11/008,770

(22) Filed: Dec. 8, 2004

(30) Foreign Application Priority Data
Dec. 9, 2003 (JP) 2003-410311

(51) Int. Cl. H01L 21/336

(52) U.S. Cl. 438/197

(57) ABSTRACT

A semiconductor device and a method of manufacturing the same are provided. An underlayer film including nitrogen is formed on a predetermined region on an element isolation region, the predetermined region extending from a border of an active element forming region to the element isolation region side. Silicon or a mixed crystal of silicon or germanium is selectively formed on the underlayer film. Then the silicon or the mixed crystal of silicon and germanium is turned into a conductive film by ion implantation of a dopant or further making it to be a silicide. Subsequently, the conductive film formed on the element isolation region is electrically connected to an electrical wiring.

### RELATED APPLICATIONS

This application claims priority to Japanese Patent Application No. 2003-410311 filed Dec. 9, 2003 which is hereby expressly incorporated by reference herein in its entirety.

### BACKGROUND

1. Technical Field

The present invention relates to a structure of a transistor formed on a semiconductor substrate and a method of manufacturing the same and, more specifically, to an optimum configuration among an electrical wiring and a source part and a drain part of the transistor, and a method of manufacturing the configuration.

2. Related Art

Due to the demands for highly integrated semiconductor elements, it is desirable to downsize a metal insulator semiconductor field effect transistor (MISFET). In addition, low power consumption and high-speed operation are requested as characteristics of the MISFET.

Because of such demands, elements such as the MISFET are being miniaturized. However, while an integration degree is increased due to the micro miniaturization, it becomes difficult to improve element performance as expected. This is caused by the following factors. Parasitic resistance and parasitic capacitance of the element relatively increase compared to channel resistance and gate capacitance. In addition, short channel effect that is an undesirable phenomenon inherent to the miniaturized MISFET becomes predominant.

In order to solve the above-mentioned problem, for example, a raised structure is employed to the source part and drain part, and electrical contacts are made on a local oxidation of silicon (LOCOS) that is an element isolation region (refer to Japanese Unexamined Patent Publication No.6-84939).

However, the following problems are included in Publication No. 6-84939. In Publication No. 6-84939, the isolation of polysilicon film or amorphous silicon film that are formed on an element isolating insulating film is not cited. If nothing is done, understandably, each MISFET is electrically shorted to each other, thereby resulting in malfunction of the circuit.

Thus, obviously, it is assumed that a process is conducted in which electrical connections among each element are cut so as to isolate the elements. However, such an element configuration may involve the following problems.

FIG. 10A shows an example of a planar configuration of the MISFET formation in the Publication No. 6-84939. FIG. 10B is a sectional view taken along line A-A in FIG. 10A.

FIG. 10A will be explained first. A surrounding area shown in the figure forms the LOCOS to be an element isolation region 2. A square frame having the width shown at the center part is a polysilicon film or an amorphous silicon film that are formed on a LOCOS 2 to be a second forming film 23. Inside the frame at the center is a MISFET forming region 3, on which a single crystal silicon film 22 is formed. An elongated rectangle shown at the center of the figure is a gate part 8, in which a gate electrode 7 is formed on a gate insulating film 6. Outside the gate electrode 7, a sidewall 12 protecting a side face of the gate part 8 is formed. The gate part 8 is formed above the second forming film 23 and the single crystal silicon film 22. A contact part 7a of the gate electrode 7 illustrated as a square is formed on the LOCOS 2 located at the upper side of the figure.

FIG. 10B will now be explained. In FIG. 10B illustrating the sectional view taken along the line A-A of a silicon substrate 1, the LOCOS 2 is formed at both sides of the figure. The part sandwiched by the LOCOS 2 is the MISFET forming region 3. The single crystal silicon 22 formed by a vapor phase epitaxial growth method is formed on the MISFET forming region 3. A polysilicon (or amorphous silicon) 23 formed by the vapor phase epitaxial growth method is formed from the border between the LOCOS 2 and the MISFET forming region 3 to the surface of the LOCOS 2. The gate insulating film 6 is formed on the single crystal silicon 22 and the polysilicon (or amorphous silicon) 23. The gate electrode 7 is formed so as to cover the gate insulating film 6. The sidewall 12 is formed to the side face of the gate electrode 7.

The gate insulating film 6 is a silicon oxide film formed by a thermal oxidation method. In this case, a good silicon oxide film 6 can be obtained because the single crystal silicon film 22 is formed on the MISFET forming region. In contrast, if the silicon oxide film 6 is formed on the polysilicon film (amorphous silicon film) 23 that is formed on the LOCOS 2 by thermal oxidation, the film quality is worse than the silicon oxide film 6 formed on the single crystal silicon film 22 by the thermal oxidation. Therefore, in the silicon oxide film 6 formed on the LOCOS 2 as the gate insulating film, leakage currents are large and dielectric breakdowns easily occur. In addition, since the film thickness of the gate insulating film becomes thinner with miniaturization of the MISFET, deterioration of the film quality of the gate insulating film 6 can adversely affect the characteristics of the MISFET.

The present invention first aims to provide a semiconductor device and a method of manufacturing the same in order to reduce parasitic capacitance at a source part and drain part caused by downsizing the transistors. The invention secondly aims to provide a semiconductor device and a method of manufacturing the same in order to reduce parasitic capacitance at a source part and drain part, the semiconductor and the method of manufacturing having a structure that can reduce defects of active elements.

### SUMMARY

***In order to solve the above-mentioned problem, a semiconductor device provided with a semiconductor substrate of a first aspect of the present invention includes an active element forming region for forming active elements, an element isolation region for isolating one element from another element, an underlayer film including nitrogen formed on a predetermined region on the element isolation region, the predetermined region extending from a border of the active element forming region to the element isolation region side, and a conductive film formed on the active element forming region and the underlayer film.

According to the configuration, by forming the underlayer film including nitrogen on the predetermined region on the element isolation region, the predetermined region extending from the border of the active element forming region to the element isolation region side, a silicon film or a mixed crystal film of silicon and germanium can readily and selectively be formed on the underlayer film. The silicon film or the mixed crystal film of silicon and germanium can readily be turned into a conductive film by ion implantation of a dopant or further making it to be a silicide. Since the conductive film can be electrically connected to the active element, the electrical connection to an electrical wiring can be conducted in the element isolation region, not the active element forming region. This makes it possible to reduce the area of a source part or a drain part, for example, in a MIS field effect transistor. The reduction of the area of the source part and the drain part has an effect of reducing parasitic capacitance. In addition, a raised structure of the source/drain region can suppress a single channel effect and reduce a junction leakage caused by the silicide. Further, since the contact of the source part and the drain part can be located on the LOCOS, there is an effect of widening the layout design freedom.

Also, in the above-described semiconductor device, the conductive film includes the silicide. The underlayer film is a silicon nitride film or a silicon oxynitride film.

According to the configuration, the underlayer of the silicon nitride film or the silicon oxynitride film can more readily form a silicon film that becomes the silicide or the mixed crystal film of silicon and germanium that are the conductive film.

In addition, the semiconductor device includes an interlayer insulating film formed on the semiconductor substrate, an electrical wiring formed on the interlayer insulating film, and a conductive layer that is formed so as to penetrate the interlayer insulating film to electrically connect the conductive film formed on the element isolation region to the electrical wiring.

According to the configuration, the device includes the structure in which the contact is conducted on the element isolation region, preferably leading the process margin of manufacturing processes to be increased.

In addition, in the semiconductor device, the active element formed to the active element forming region is a MISFET. Also, the semiconductor device includes a gate part including a gate insulating film and a gate electrode that are formed to the active element forming region and a conductive film formed on the element isolation region that is located at both sides of the gate part, the conductive film being patterned so as to exclude a lower layer of the gate insulating film.

According to the configuration, the surface of the semiconductor substrate to which the gate part including the gate insulating film and the gate electrode is formed is flat and formed with single crystal. Thus, factors causing a deterioration of the film quality of the gate insulating film are lessened. As a result, characteristic defects of the active element can be reduced.

A method of manufacturing a semiconductor device provided with a semiconductor substrate on which an element isolation region and an active element forming region are formed of a second aspect of the invention includes an underlayer forming process forming a silicon nitride film or a silicon oxynitride film on the entire face of the semiconductor substrate, an underlayer removing process leaving the silicon nitride film or the silicon oxynitride film as the underlayer film in a predetermined region which extends from a border of the active element forming region to the element isolation region side as well as removing the rest of the underlayer film except the predetermined region, a gate part forming process forming a gate part including a gate insulating film and a gate electrode to the active element forming region, a contact region forming process forming a contact region of a source part and a drain part to the active element forming region by ion implantation, and a vapor phase selective epitaxial process forming a sidewall made of an insulating film to a side face of the gate part, and forming a single crystal silicon film or a single crystal film that is made of mixed crystal of silicon and germanium to the source part and the drain part, and a polysilicon film or a polycrystal film that is made of mixed crystal of silicon and germanium on the silicon nitride film or the silicon oxynitride film by a vapor phase selective epitaxial growth method.

According to the method, the silicon nitride film or the silicon oxynitride film can be formed to the predetermined region extending from the border of the active element forming region to the element isolation region side. Then, the silicon film or the mixed crystal film of silicon and germanium can be selectively formed only to the active element forming region and the region to which the silicon nitride film or the silicon oxynitride film is formed by the vapor phase selective epitaxial growth method. The silicon film or the mixed crystal film of silicon and germanium can readily be turned into a conductive film, for example, by making it to be the silicide. Since the conductive film can be electrically connected to the active element, the electrical connection to the electrical wiring can be conducted in the element isolation region, not the active element forming region. This makes it possible to reduce the area of the source part and the drain part, for example, in the MIS field effect transistor.

A method of manufacturing a semiconductor device provided with a semiconductor substrate on which an element isolation region and an active element forming region are formed of a third aspect of the invention includes a gate part forming process forming a gate part including a gate insulating film and a gate electrode to the active element forming region, an underlayer forming process forming a silicon nitride film or a silicon oxynitride film on the entire face of the semiconductor substrate, an underlayer removing process leaving the silicon nitride film or the silicon oxynitride film as the underlayer film in a predetermined region which extends from a border of the active element forming region to the element isolation region side as well as removing the rest of the underlayer film except the predetermined region, a contact region forming process forming a contact region of a source part and a drain part to the active element forming region by ion implantation, and a vapor phase selective epitaxial process forming a sidewall made of an insulating film to a side face of the gate part, and forming a single crystal silicon film or a single crystal film that is made of mixed crystal of silicon and germanium to the source part and the drain part, and a polysilicon film or a polycrystal film that is made of mixed crystal of silicon and germanium on the silicon nitride film or the silicon oxynitride film by a vapor phase selective epitaxial growth method.

According to the method, even if the gate part is first formed, accordingly, the silicon nitride film or the silicon oxynitride film can be formed to the predetermined region extending from the border of the active element forming region to the element isolation region side. Therefore, the same effects as those mentioned above can be obtained in this aspect of the invention.

A method of manufacturing a semiconductor device provided with a semiconductor substrate in which a silicon nitride film is formed on an element isolation region and an active element forming region of a fourth aspect of the invention includes a resist pattern forming process removing photoresist formed on a desired region of the element isolation region and the silicon nitride film to form an opening by a photolithography method, a nitrogen ion implanted region forming process implanting nitrogen ions into the entire surface of the semiconductor substrate so as to form a nitrogen ion implanted region to the element isolation region in the opening, a silicon nitride film removing process removing the photoresist and the silicon nitride film, a gate part forming process forming a gate part including a gate insulating film and a gate electrode to the active element forming region, a contact region forming process forming a contact region of a source part and a drain part to the active element forming region by ion implantation, and a vapor phase selective epitaxial process forming a sidewall made of an insulating film to a side face of the gate part, and forming a single crystal silicon film or a single crystal film that is made of mixed crystal of silicon and germanium to the source part and the drain part, and a polysilicon film or a polycrystal film that is made of mixed crystal of silicon and germanium on the nitrogen ion implanted region by a vapor phase selective epitaxial growth method.

According to the method, the nitrogen ion implanted region can be formed to the predetermined region extending from the border of the active element forming region to the element isolation region side in the following way. In the semiconductor substrate in which the silicon nitride film is formed on the element isolation region and the active element forming region, the photoresist film that is formed on the desired region of the element isolation region and the silicon nitride film is removed to form an opening by the photolithography method. Then, nitrogen ions are implanted into the entire face of the semiconductor substrate. Next, the silicon film or the mixed crystal film of silicon and germanium can be selectively formed only to the active element forming region and the nitrogen ion implanted region by the vapor phase selective epitaxial growth method. Therefore, the same effects as those mentioned above can be obtained by this method.

A method of manufacturing a semiconductor device provided with a semiconductor substrate on which an element isolation region and an active element forming region are formed of a fifth aspect of the invention includes an underlayer film forming process forming a silicon nitride film or a silicon oxynitride film on the entire face of the semiconductor substrate, an underlayer removing process leaving the silicon nitride film or the silicon oxynitride film as the underlayer film in a predetermined region which extends from a border of the active element forming region to the element isolation region side as well as removing the rest of the underlayer film except the predetermined region, a gate part forming process forming a gate part including a gate insulating film and a gate electrode made of a metal element to the active element forming region, a contact region forming process forming a contact region of a source part and a drain part to the active element forming region by ion implantation, a silicon film forming process forming a sidewall made of an insulating film to a side face of the gate part and forming single crystal silicon to the source part and the drain part, and polysilicon on the silicon nitride film or the silicon oxynitride film at the range of 500 degrees centigrade or more to 600 degrees centigrade or less by a vapor phase selective epitaxial growth method, and a mixed crystal film of silicon and germanium forming process forming a single crystal that is made of mixed crystal of silicon and germanium on the single crystal silicon film or a polycrystal film that is made of mixed crystal of silicon and germanium on the polysilicon film at the range of 500 degrees centigrade or more to 600 degrees centigrade or less by a vapor phase selective epitaxial growth method.

According to the method, the silicon nitride film or the silicon oxynitride film can be formed to the predetermined region extending from the border of the active element forming region to the element isolation region side. Also, since gate electrode is made of metal, a low temperature process at 600 degrees centigrade or less can be used after forming the gate electrode. In the next vapor phase selective epitaxial growth method, the silicon film is formed at a temperature range of 500 degrees centigrade or more and 600 degrees centigrade or less. Then, the mixed crystal film of silicon and germanium is formed. While the silicone film alone can be formed at above-mentioned temperature range, the throughput of the vapor phase selective epitaxial process is reduced because the film forming speed is low. Also, in the case where only the mixed crystal film of silicon and germanium is formed, even though the film forming speed is fast, there may be a case where a film cannot be formed evenly or no film is formed because the film is readily affected by the underlayer. Therefore, in the fifth aspect of the invention, the influence of the underlayer can be reduced by forming the silicon film to be thin. Then, a good-quality mixed crystal film of silicon and germanium can be formed. The silicon film and the mixed crystal film of silicon and germanium can readily be turned into a conductive film, for example, by making it to be the silicide. Since the conductive film can be electrically connected to the active element, the electrical connection to the electrical wiring can be conducted in the element isolation region, not the active element forming region. This makes it possible to reduce the area of the source part and the drain part, for example, in a MIS field effect transistor.

A method of manufacturing a semiconductor device provided with a semiconductor substrate on which an element isolation region and an active element forming region are formed of a sixth aspect of the invention includes a gate part forming process forming a gate part including a gate insulating film and a gate electrode made of a metal element to the active element forming region, an underlayer film forming process forming a silicon nitride film or a silicon oxynitride film on the entire face of the semiconductor device, an underlayer removing process leaving the silicon nitride film or the silicon oxynitride film as the underlayer film in a predetermined region which extends from a border of the active element forming region to the element isolation region side as well as removing the rest of the underlayer film except the predetermined region, a contact region forming process forming a contact region of a source part and a drain part to the active element forming region by ion implantation, a silicon film forming process forming a sidewall made of an insulating film to a side face of the gate part, and forming single crystal silicon to the source part and the drain part, and polysilicon on the silicon nitride film or the silicon oxynitride film at the range of 500 degrees centigrade or more to 600 degrees centigrade or less by a vapor phase selective epitaxial growth method, and a mixed crystal film of silicon and germanium forming process forming a single crystal film that is made of mixed crystal of silicon and germanium on the single crystal silicon film or a polycrystal film that is made of mixed crystal of silicon and germanium on the polysilicon film at the range of 500 degrees centigrade or more to 600 degrees centigrade or less by a vapor phase selective epitaxial growth method.

According to the method, even if the gate part including the gate electrode made of metal is first formed, accordingly, the silicon nitride film or the silicon oxynitride film can be formed to the predetermined region extending from the border of the active element forming region to the element isolation region side. Also, by forming a double-layer structure of the silicon film and the mixed crystal film of silicon and germanium by the vapor phase selective epitaxial growth method, the film that becomes the conductive film made of the silicide can be formed by even though the low temperature process of 500 degrees centigrade or more and 600 degrees centigrade or less. Therefore, the same effects as those mentioned above can be obtained in this aspect of the invention.

A method of manufacturing a semiconductor device provided with a semiconductor substrate in which a silicon nitride film is formed on an element isolation region and an active element forming region of a seventh aspect of the invention includes a resist pattern forming process removing photoresist formed on a desired region of the element isolation region and the silicon nitride film to form an opening by a photolithography method, a nitrogen ion implanted region forming process implanting nitrogen ions into the entire surface of the semiconductor substrate so as to form a nitrogen ion implanted region to the element isolation region in the opening, a silicon nitride film removing process removing the photoresist and the silicon nitride film, a gate part forming process forming a gate part including a gate insulating film and a gate electrode to the active element forming region, a contact region forming process forming a contact region of a source part and a drain part to the active element forming region by ion implantation, a silicon film forming process forming a sidewall made of an insulating film to a side face of the gate part, and forming single crystal silicon to the source part and the drain part, and polysilicon on the silicon nitride film or the silicon oxynitride film at the range of 500 degrees centigrade or more to 600 degrees centigrade or less by a vapor phase selective epitaxial growth method, and a mixed crystal film of silicon and germanium forming process forming a single crystal film that is made of mixed crystal of silicon and germanium on the single crystal silicon film or a polycrystal film that is made of mixed crystal of silicon and germanium on the polysilicon film at the range of 500 degrees centigrade or more to 600 degrees centigrade or less by a vapor phase selective epitaxial growth method.

According to the method, the nitrogen ion implanted region can be formed to the predetermined region extending from the border of the active element forming region to the element isolation region side in the following way. In the semiconductor substrate in which the silicon nitride film is formed on the element isolation region and the active element forming region, the photoresist film that is formed on a desired region of the element isolation region and the silicon nitride film is removed to form an opening by the photolithography method. Then, nitrogen ions are implanted into the entire face of the semiconductor substrate. Also, since the gate electrode is formed with metal, a low temperature process can be used. However, by forming the double-layer structure of the silicon film and the mixed crystal film of silicon and germanium by the vapor phase selective epitaxial growth method, the film that becomes the conductive film made of the silicide can be formed by even though the low temperature process of 500 degrees centigrade or more and 600 degrees centigrade or less. Next, the silicon film or the mixed crystal film of silicon and germanium can be selectively formed only to the active element forming region and the nitrogen ion implanted region by the vapor phase selective epitaxial growth method. Therefore, the same effects as those mentioned above can be obtained by this method.

In addition, in the seventh aspect of the invention, the gate insulating film and the underlayer film are formed so not to overlap each other in the gate part forming process or the underlayer film forming process.

According to the method, by forming the underlayer film and the part forming the gate part including the gate insulating film and the gate electrode so not to overlap each other, the gate insulating film can be formed only to the active element forming region whose surface is flat and single crystal. Therefore, factors causing the deterioration of the film quality of the gate insulating film are lessened. As a result, characteristic defects of the active element can be reduced.

In addition to the above-mentioned aspects of the invention, the method of manufacturing a semiconductor device includes a process forming a metal film to the entire surface of the semiconductor substrate, a process performing a heat treatment to the semiconductor substrate so as to form a suicide, and a process removing an excess metal film that is not turned into the silicide on the semiconductor substrate after the vapor phase selective epitaxial process.

According to the method, in addition to the effects of the above-mentioned aspects of the invention, the contact to the electrical wiring can be conducted even on the element isolation region by forming the silicon film or the mixed crystal film of silicon and germanium in the vapor phase selective epitaxial process and by turning a part of the film to the silicide.

Further, the method of a semiconductor device includes an interlayer insulating film forming process forming an interlayer insulating film on the semiconductor substrate, an opening forming process forming an opening to the interlayer insulating film on the silicide formed on the element isolation region, a conductive layer forming process plugging a conductive member into the opening so as to form a conductive layer, an electrical wiring film forming process forming an electrical wiring film on the interlayer insulating film, and an electrical wiring forming process forming an electrical wiring by patterning the electrical wiring film.

According to the method, the electrical connection of the active element can be conducted by forming the electrical wiring on the interlayer insulating film and forming the conductive layer so as to be electrically connected to the silicide on the element isolation region. This makes it possible to reduce the area of a source part and a drain part, for example, in the case where the active element is the MISFET. The reduction of the area of the source part and the drain part has an effect of reducing parasitic capacitance. Further, since the contact of the source part and the drain part can be located on the LOCOS, there is an effect of widening the layout design freedom.

### BRIEF DESCRIPTION OF THE DRAWINGS

FIGS. 1A through 1D are process sectional views illustrating manufacturing processes of a semiconductor device of a first embodiment of the present invention.

FIG. 2 is a sectional view illustrating an example of the semiconductor device manufactured in the embodiment.

FIGS. 3A through 3C are process sectional views illustrating manufacturing processes of the semiconductor device of the first embodiment.

FIG. 4A is a plan view of the semiconductor device manufactured in the embodiment; FIG. 4B is a sectional view taken along line B-B of the semiconductor device manufactured in the embodiment.

FIGS. 5A through 5D are process sectional views illustrating each manufacturing process of a semiconductor device of a second embodiment of the present invention.

FIGS. 6A through 6C are process sectional views illustrating each manufacturing process of the semiconductor device of the second embodiment.

FIGS. 7A through 7D are process sectional views illustrating each manufacturing process of a semiconductor device of a third embodiment of the present invention.

FIGS. 8A through 8D are plan views illustrating each manufacturing process of the semiconductor device of the third embodiment.

FIG. 9 is a sectional view illustrating manufacturing processes of a semiconductor device in a fourth embodiment of the invention.

FIG. 10A is a plan view of the semiconductor device of a related art; FIG. 10B is a section view taken along line A-A in the plan view of the semiconductor device of the related art.

### DETAILED DESCRIPTION

### First Embodiment

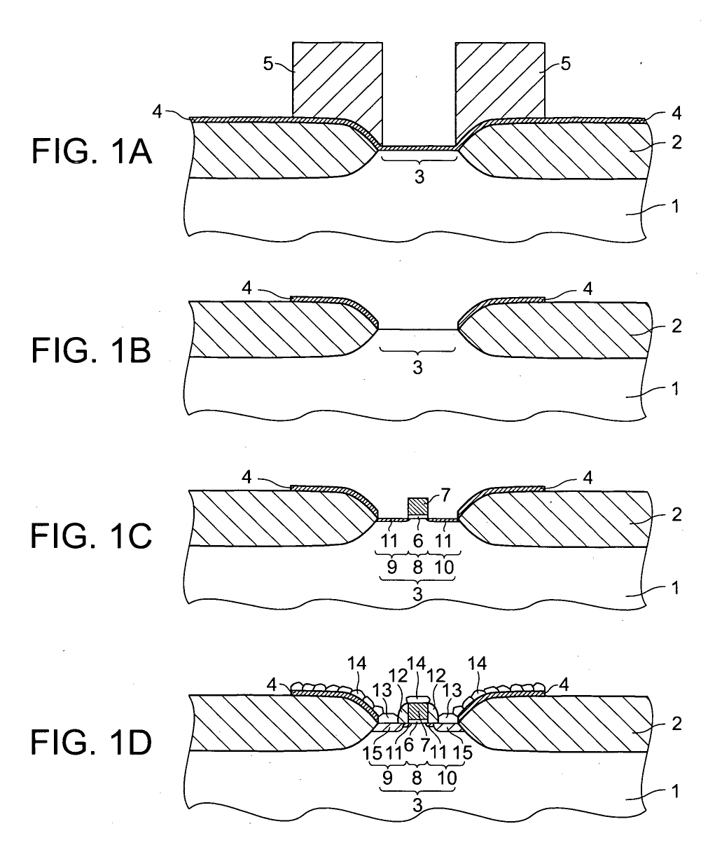

A first embodiment according to the present invention will now be explained using FIGS. 1 through 4.

FIGS. 1A through 1D are process sectional views illustrating the manufacturing processes of a MISFET that is the semiconductor device of the first embodiment.

In FIG. 1A, a forming process of a LOCOS that is an element isolation region, a MISFET forming region that is an active element forming region, and an underlayer film formed by a vapor phase selective epitaxial growth method will be explained. First, the forming process of the LOCOS 2 and the MISFET forming region 3 will be explained. A silicon oxide film (not shown) is formed on the entire surface of a silicon substrate 1. Subsequently, a silicon nitride film (not shown) is formed on the silicon oxide film. The silicon nitride film excluding the part becoming the MISFET forming region 3 is removed so as to expose the silicon oxide film of the part becoming an element isolation region 2. Then, the silicon oxide film is grown to be thicker by performing thermal oxidation in a thermal oxidation furnace. The silicon oxide film grown thicker becomes the LOCOS 2. After forming the LOCOS 2, the silicon nitride film of the part becoming the MISFET forming region 3 is removed. In this way, the LOCOS 2 and the MISFET forming region 3 are formed on the silicon substrate 1. Next, the forming process of an underlayer film 4 will be explained. On the entire surface of the silicon substrate 1 on which the LOCOS 2 and the MISFET forming region 3 are formed, the silicon nitride film is formed as the underlayer film 4 by a plasma enhanced chemical vapor deposition (PECVD) method. Then, a photoresist 5 is patterned by a photolithography method.

The pattern of the photoresist 5 is formed such that the photoresist 5 remains only from the border at the MISFET forming region 3 to a part of the LOCOS 2.

By performing the above-mentioned forming processes of the LOCOS 2, the MISFET forming region 3, and the silicon nitride film 4 as the underlayer film, the following structural body is obtained. That is, the LOCOS 2 is provided on the silicon substrate 1 that is a semiconductor substrate as the element isolation region at both right and left side in the figure. The center area sandwiched by the LOCOS 2 is the MISFET forming region 3 that is the active element forming region. The silicon nitride film 4 is formed on the LOCOS 2 and the MISFET forming region 3 for the underlayer film of an epitaxial growth film. A photoresist 5 formed in a pattern is formed on the silicon nitride film 4.

In FIG. 1B, an underlayer film removing process will be explained.

In the silicon substrate 1 that has been formed as shown in FIG. 1A, the silicon nitride film 4 that is the underlayer film is removed by a dry etching method with the photoresist 5 as a mask. Then, the photoresist 5 is removed and the surface of the silicon substrate 1 is cleaned.

By performing the above-mentioned removing process of the silicon nitride film 4, the following structural body is obtained. That is, the silicon nitride film 4 is formed from the border between the MISFET forming region 3 and the LOCOS 2 to a part of the LOCOS 2.

In FIG. 1C, a forming process of a gate part, and an extension region of a source part and a drain part will be explained. First, the forming process of a gate part 8 will be explained. A silicon oxide film is formed on the silicon substrate 1 as a gate insulating film 6. Then, a polysilicon film is formed as a gate electrode 7. Subsequently, the gate part 8 is formed at nearly a center part of the MISFET forming region 3 using a photolithography method and a dry etching method. Next, the forming process of an extension region 11 of a source part 9 and a drain part 10 will be explained. The extension region 11 is formed in the silicon substrate 1 of the source part 9 and the drain part 10 by ion implantation. In this embodiment, while the gate electrode 7 is formed by the polysilicon, metals such as tantalum (Ta) or the like may be used in addition to the polysilicon.

By performing the above-mentioned forming processes of the gate part 8, and the extension region 11 of the source part 9 and the drain part 10, the following structural body is obtained. That is, the gate part 8 that includes the gate insulating film 6 and the gate electrode 7 is formed at nearly a center part on the MISFET forming region 3. Also, both sides of the gate part 8 on the MISFET forming region 3 are the source part 9 and the drain part 10. The extension region 11 formed by diffusing impurities is formed in the vicinity of the surface of the silicon substrate 1 that becomes the source part 9 or the drain part 10.

In FIG. 1D, a sidewall forming process, a vapor phase selective epitaxial process, and a contact region forming process will be explained. First, in the forming process of a sidewall 12, a silicon oxide film is formed as the sidewall protecting the side face of the gate part 8 by the PECVD method. Then, the silicon oxide film is etched by a dry etching method such that only the silicon oxide film on the side face of the gate part 8 remains. In this way, the sidewall 12 is formed.

Next, the vapor phase selective epitaxial growth process will be explained. The silicon substrate 1 is put into a vapor phase epitaxial growth furnace so as to be subjected to pre-annealing at a temperature range from 700 degrees centigrade to 800 degrees centigrade in a vacuum. Then, by supplying disilane (hereinafter referred to as Si₂H₆) gas into the furnace at a temperature range from 550 degrees centigrade to 800 degrees centigrade, a single crystal silicon film 13 and a polysilicon film 14 are formed on the silicon substrate 1. In this case, the single crystal silicon film 13 and the polysilicon film 14 that are formed are so-called non-doped film containing no impurities. Here, the formation of the single crystal silicon film 13 and the polysilicon film 14 by the vapor phase epitaxial growth method can be selectively grown by controlling growing conditions according to the surface conditions. In this embodiment, the single crystal silicon film 13 is grown on the surface of the source part 9 and the drain part 10 that are on the silicon substrate 1 where the silicon surface is exposed. In contrast, the polysilicon film 14 is formed on the gate electrode 7 formed with the polysilicon film and on the silicon nitride film 4 formed on the LOCOS 2.

However, no film is grown on the LOCOS 2 and sidewall 12, both of which are formed with the silicon oxide film. From this, the silicon nitride film 4 functions as the underlayer film 4 for film forming in the vapor phase epitaxial growth method. Therefore, in the vapor phase epitaxial growth in this embodiment, the single crystal silicon film 13 is grown in the case where the underlayer film of the silicon substrate 1 is the single crystal silicon. The polysilicon film 14 is grown in the case where the underlayer film is the polysilicon or the silicon nitride. No film is grown in the case where the underlayer film is the silicon oxide.

While the single crystal silicon film 13 or the polysilicon film 14 has been explained as the film formed by the vapor phase selective epitaxial growth method, silicon-germanium mixed crystal films (hereinafter referred to as SiGe films) 24 and 25 may be applicable instead of the silicon film. For the vapor phase epitaxial growth of the SiGe films 24 and 25, pre-annealing is performed at a temperature range from 700 degrees centigrade to 800 degrees centigrade in a vacuum. Then, the SiGe films 24 and 25 can be formed by supplying the mixed gas of Si₂H₆ gas and GeH₄ gas into the furnace at a temperature range from 550 degrees centigrade to 800 degrees centigrade. In forming the silicon films 13 and 14 or the SiGe films 24 and 25 by the vapor phase epitaxial growth method, in the case where the surface of the silicon substrate 1 or the underlayer film 4 or the like are a surface or a film that contain nitrogen, it was experimentally confirmed that the films were selectively grown on the region. The formation of the silicon films 13 and 14 may be performed by alternatively supplying Si₂H₆ gas and chlorine (hereinafter referred to as Cl₂) gas. This is because selective growth is more enhanced by alternatively supplying Si₂H₆ gas and Cl₂ gas.

Next, the forming process of a contact region 15 will be explained. The ion implantation of the same conductive type as that of the extension is entirely performed to the silicon substrate 1 so as to form the contact region 15. Also, simultaneously, impurities are introduced into the single crystal silicon film 13 and the polysilicon film 14. By introducing the impurities, the electric resistance of the single crystal silicon film 13 and the polysilicon film 14 is reduced.

By performing the above-mentioned forming processes of the sidewall 12, the vapor phase selective epitaxial process, and the forming process of the contact region 15, the following structural body is obtained. That is, the sidewall 12 formed with the insulating film protecting the side face of the gate part 8 is formed. The contact region 15 is formed to the underside of the extension region 11 formed in the silicon substrate 1 of the source part 9 and the drain part 10. Also, the single crystal silicon film 13 is formed on the surface of the silicon substrate 1 of the source part 9 and the drain part 10. Further, the single crystal silicon film 13 is formed on the polysilicon film that is the gate electrode 7. The polysilicon film 14 is formed on the silicon nitride film 4 formed on the LOCOS 2.

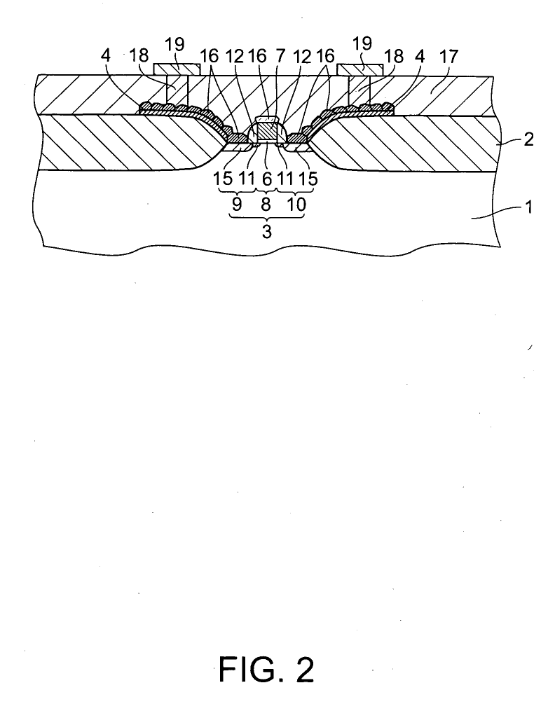

In FIG. 2, a metal film forming process for forming a silicide, a silicide forming process, a metal film removing process, an interlayer insulating film forming process, an opening part forming process, a conductive layer forming process in which a conductive material is embedded into the opening part, an electrical wiring film forming process and an electrical wiring forming process will be explained. First, the metal film forming process will be explained. A titanium film (not shown) is formed on the entire face of the silicon substrate 1 that has been formed as shown in FIG. 1D as a metal film by a sputtering method. Next, the forming process of a silicide 16 will be explained. The silicon substrate 1 is subjected to a heat treatment at a temperature from 700 degrees centigrade to 800 degrees centigrade. By the heat treatment, the titanium film formed on the single crystal silicon film 13 and the polysilicon film 14 forms a titanium silicide 16 reacted with the silicon. Next, the titanium film removing process will be explained. The silicon substrate 1 in which the titanium silicide is formed is subjected to a wet process so as to remove any unreacted titanium film. Accordingly, the titanium silicide 16 self-aligns and forms on the source part 9, the drain part 10, the gate electrode 7, and the silicon nitride film 4 on the LOCOS 2. Next, a heat treatment is conducted at a temperature from 700 degrees centigrade to 900 degrees centigrade. By the heat treatment, the titanium silicide 16 is further changed to a crystal phase having lower resistance. Next, the forming process of an interlayer insulating film 17 will be explained. The interlayer insulating film 17, which is a relatively thick silicon oxide film, is formed by the PECVD method. As concerns the silicon oxide film 17 in this case, a boro-phospho-silicate glass (BPSG), silicon oxide film including boron and phosphorous, that shows high flatness of the film formed, or the silicon oxide film 17 for which tetraethoxysilane (TEOS) are used as raw materials is used. Next, the opening part forming process will be explained. Photoresist (not shown) is formed in a pattern on the silicon oxide film that is the interlayer insulating film 17 by a photolithography method. Next, the opening part is formed by dry etching the interlayer insulating film 17 on the silicide 16 formed on the LOCOS 2. Next, the forming process of a conductive layer 18 will be explained. Tungsten (hereinafter referred to as W) is formed to the opening part as a material for the conductive layer by a chemical vapor deposition (CVD) method. Then, excess W formed by the CVD method is removed and planarized by a dry etching or chemical mechanical polishing (CMP). Next, the electrical wiring film forming process will be explained. An aluminum film is formed as an electrical wiring 19 by a sputtering method. Next, the electrical wiring forming process will be explained. The aluminum film is formed in a pattern by a photolithography method and a dry etching method so as to form the electrical wiring 19.

The following structural body is obtained by performing the above-mentioned processes: the titanium film forming process, the forming process of the silicide 16, the titanium film removing process, the forming process of the interlayer insulating film 17, the opening part forming process, the forming process of the conductive layer 18, the electrical wiring film forming process, and the forming process of the electrical wiring 19. That is, the single crystal silicon film 13 formed on the source part 9 and the drain part 10 of the silicon substrate 1, and the polysilicon film 14 formed on the silicon nitride film 4 formed on the gate electrode 7 and the LOCOS 2 become the silicide that is the conductive film 16. Either the entire or a part of the single crystal silicon film 13 or the polysilicon film 14 may be turned into the silicide 16. In addition, in the case where the gate electrode 7 is formed with a metal, not the polysilicon, no silicon film is formed on the gate electrode 7 by the vapor phase selective epitaxial growth method. Thus, the silicide 16 is not formed on the gate electrode 7. However, this is not a problem because the gate electrode itself is formed with a metal. The interlayer insulating film 17 is formed on the entire surface of the silicon substrate 1. The electrical wiring 19 is formed on the interlayer insulating film 17. In addition, in the interlayer insulating film 17, the conductive layer 18 for electrically connecting the silicide 16 formed on the LOCOS 2 to the electrical wiring 19.

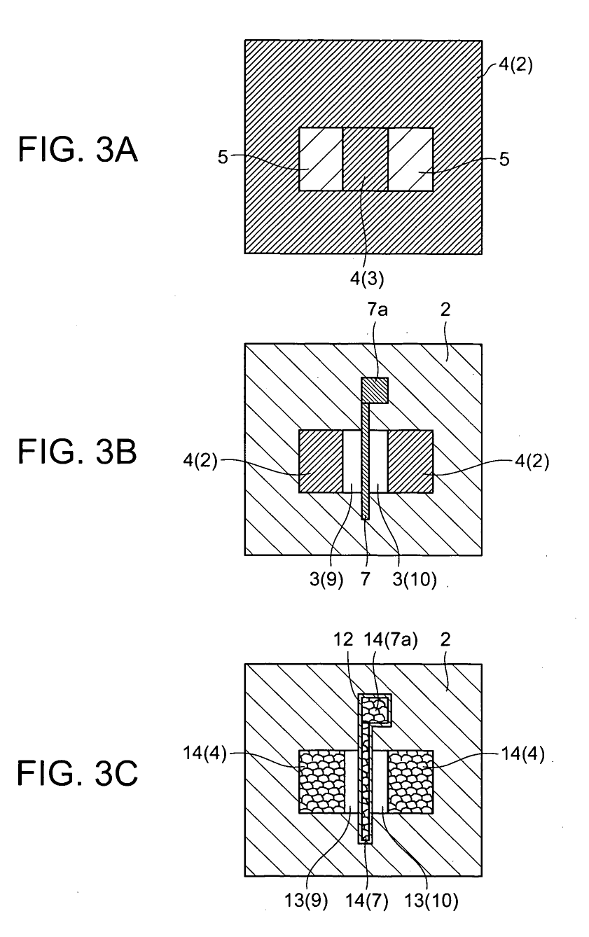

FIGS. 3A through 3C show plan views of the processes of the MISFET formed on the silicon substrate 1. FIG. 3A corresponds to the plan view of FIG. 1A in the process sectional views. FIG. 3B and FIG. 3C correspond to FIG. 1C and FIG. 1D respectively.

FIG. 3A will now be explained. The square like frame shown in the figure represents the surface of the silicon substrate 1 on which the elements are formed and in which the LOCOS 2 and one MISFET forming region 3 are included. In the square like frame, the MISFET forming region is located at the center part and surrounded with the LOCOS 2. In FIG. 3A, the silicon nitride film that is the underlayer film 4 is formed on the entire face of the silicon substrate 1. The photoresist 5 that is formed in a pattern so as to touch one edge of the MISFET forming region 3 is formed at two parts sandwiching the MISFET forming region 3 at the center part.

FIG. 3B will now be explained. The silicon nitride film 4 on the MISFET forming region 3 and the silicon nitride film on the LOCOS 2 excluding the part on which the photoresist 5 is formed are removed. The gate part 8, which is represented as an elongated rectangle, is formed from on the LOCOS 2, across the center on the MISFET forming region 3, and onto the LOCOS 2. The surface of the gate part 8 is the gate electrode 7 formed with the polysilicon. The gate insulating film 6 is formed under the gate electrode 7 with the silicon oxide. In addition, a contact part 7a for electrical connection is formed at the gate part 8 on the LOCOS 2 located at the upper side in the figure. Also, in the MISFET forming region 3, one region of both sides of the gate part 8 is the source part 9 and the other region is the drain part 10.

FIG. 3C will now be explained. The sidewall 12 formed with the silicon oxide is formed to the side face of the gate part 8. The single crystal silicon film 13 is formed on the source part 9 and the drain part 10 by the vapor phase selective epitaxial method. Also, the polysilicon film 14 is formed on the gate electrode 7 and the silicon nitride film 4.

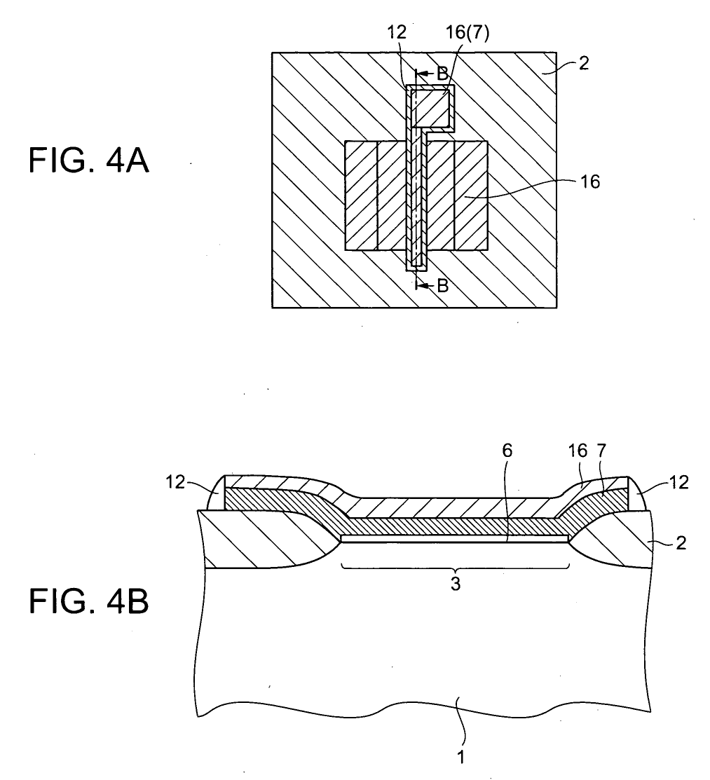

FIG. 4A shows the plan view of the MISFET formed on the silicon substrate 1. After forming the single crystal silicon film 13 or the polysilicon film 14, the suicide 16 is formed on the source part 9, the drain part 10, the gate electrode 7 and the silicon nitride film 4. As understood from the plan view, since the silicide 16 that is the conductive film is also formed on a part of the LOCOS 2, the electrical connection of the source part 9 and the drain part 10 can be conducted on the LOCOS 2. Therefore, the area of the source 9 and the drain part 10 can be reduced as much as possible.

FIG. 4B shows a sectional view taken along line B-B passing through the center of the gate part 8 in FIG. 4A. In the silicon substrate 1, the LOCOS 2 is formed at both sides in a longitudinal direction of the gate part 8 to sandwich the MISFET forming region 3. The sidewall 12 is formed at both end faces in the longitudinal direction of the gate part 8 on the LOCOS 2. The single crystal silicon film 13 and the polysilicon film 14 are selectively grown only on the region of both sides sandwiching the gate part 8 so as to become the suicide 16 to form the conductive film. The gate insulating film is formed only on the single crystal silicon.

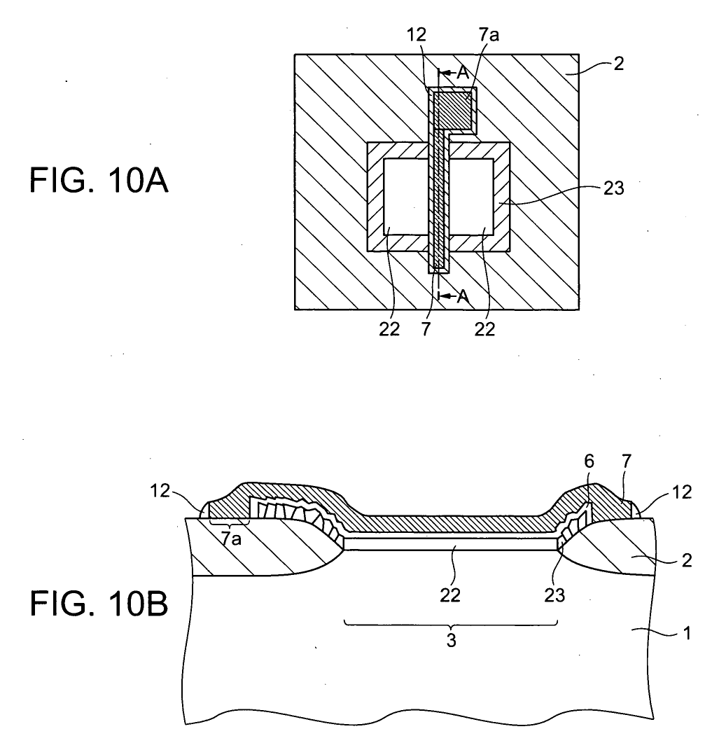

That is, as compared with the sectional view in FIG. 10B, the gate insulating film 6 can be well formed by this embodiment, thereby enabling element defects caused by the gate insulating film 6 to be reduced.

In addition, in the embodiment, a raised structure is employed by forming the single crystal silicon film 13 at the source part 9 and the drain part 10 by the vapor phase selective epitaxial growth method. If the source part 9 and the drain part 10 have a common structure, not the raised structure, the following problems associated with the micro miniaturization of the MISFET or the like arise. That is, if the junction of the source part 9 and the drain part 10 become shallow, junction leakage caused by the suicide 16 becomes a problem. Therefore, it is necessary to form the junction of the source part 9 and the drain part 10 to have a sufficient depth.

However, when the junction of the source part 9 and the drain part 10 are formed to be deep, the short channel effect occurs. Thus, it is inevitable to form the sidewall 12 made of the insulating film to have a sufficient thickness. However, by forming the sidewall 12 to be thick, a problem arises in which a resistivity increases at the extension region 11 below the lower part of the sidewall 12.

In contrast, in a fully depleted (FD) type MISFET formed on a silicon on insulator (SOI) substrate 1, the source part 9 and the drain part 10 can reach to a buried oxide (BOX), and, therefore, the junction leakage caused by the silicide 16 does not easily take place. However, because the silicon layer of on the surface of the SOI substrate 1 is thin and the silicide 16 readily reaches to the BOX layer, an area between the silicide 16 and the silicon layer shrinks significantly, creating another problem of increasing a contact resistivity.

The above-mentioned problems can be solved by making the source part 9 and the drain part 10 to have a raised structure.

The effects of the first embodiment will be described below.

(1) By forming the silicon nitride film 4 on the region on the LOCOS 2, the region extending from the border of the MISFET forming region 3 to the LOCOS 2 side, the single crystal silicon film 13 can be formed on the MISFET forming region 3 and the polysilicon film 14 can be formed on the silicon nitride film 4 and the gate electrode 7.

(2) Since the silicon nitride film is formed as the underlayer film 4, the single crystal silicon film 13 and the polysilicon film 14 can easily be formed by the vapor phase epitaxial growth method.

(3) By turning the single crystal silicon film 13 and the polysilicon film 14 to the silicide, the silicide 16 can easily be formed as the conductive film.

(4) The electrical wiring 19 is formed on the interlayer insulating film 17. The conductive layer 18 is formed so as to electrically connect the silicide 16 on the LOCOS 2 to the electrical wiring 19. This makes it possible to conduct the electrical connection of the source part 9 and the drain part 10 on the LOCOS 2. Thus, a configuration in which contacts are conducted on the element isolation region can obtain the effect of increasing the process margin in manufacturing processes. Also, the effect of increasing the layout design freedom of transistor wirings can be obtained.

(5) The electrical wiring 19 is formed on the interlayer insulating film 17. The conductive layer 18 is formed so as to electrically connect the silicide 16 on the LOCOS 2 to the electrical wiring 19. This makes it possible to conduct the electrical connection of the source part 9 and the drain part 10 on the LOCOS 2. Accordingly, no contacts need be directly formed to the source part 9 and the drain part 10. Therefore, the area of the source 9 and the drain part 10 can be reduced. As a result, the reduction of the area of the source part 9 and the drain part 10 can reduce parasitic capacitance at the source part 9 and the drain part 10. In addition, the contacts of the source part 9 and the drain part 10 can be arranged on the LOCOS 2. This makes it possible to obtain the effect of widening the layout design freedom.

(6) Since the gate insulating film 6 of the gate part 8 is formed only on the single crystal silicon, a better quality film can easily be obtained as compared with the film formed on the polysilicon. As a result, leakage current defects from the gate insulating film 6 can be reduced.

(7) Since the source part 9 and the drain part 10 have a raised structure, the problem associated with the micro miniaturization of MISFET that is the junction leakage between the silicide 16 and the source part 9 and the drain part 10 can be avoided. Also, it is not necessary to form the junction of the source part 9 and the drain part 10 to have a great depth. Thus, the short channel effect can be reduced. Further, in the SOI substrate, the area between the silicide 16 and the silicon layer is not reduced. Thus, the increase of the contact resistivity can be suppressed.

### Second Embodiment

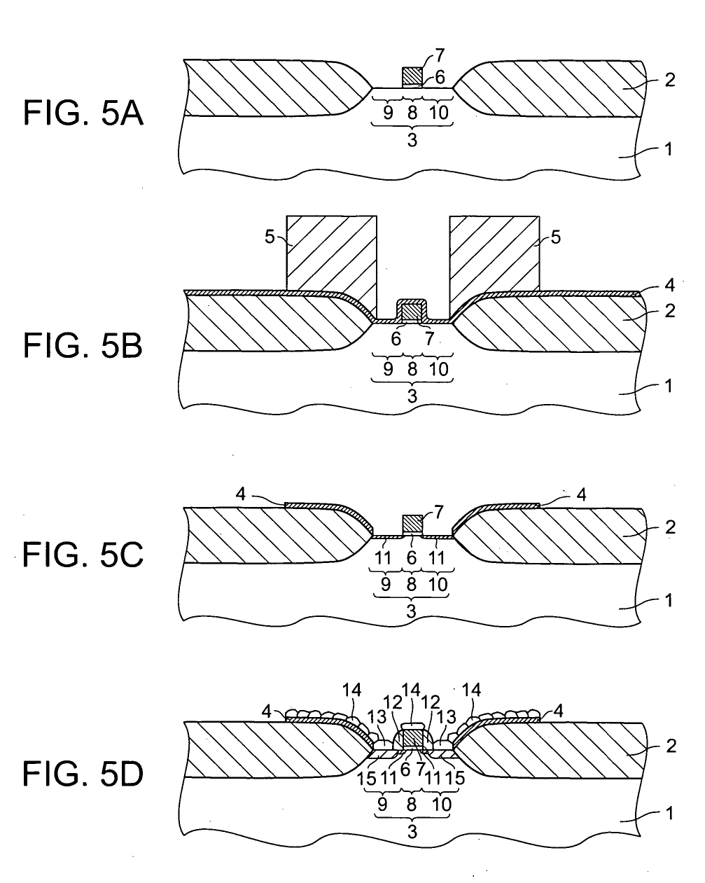

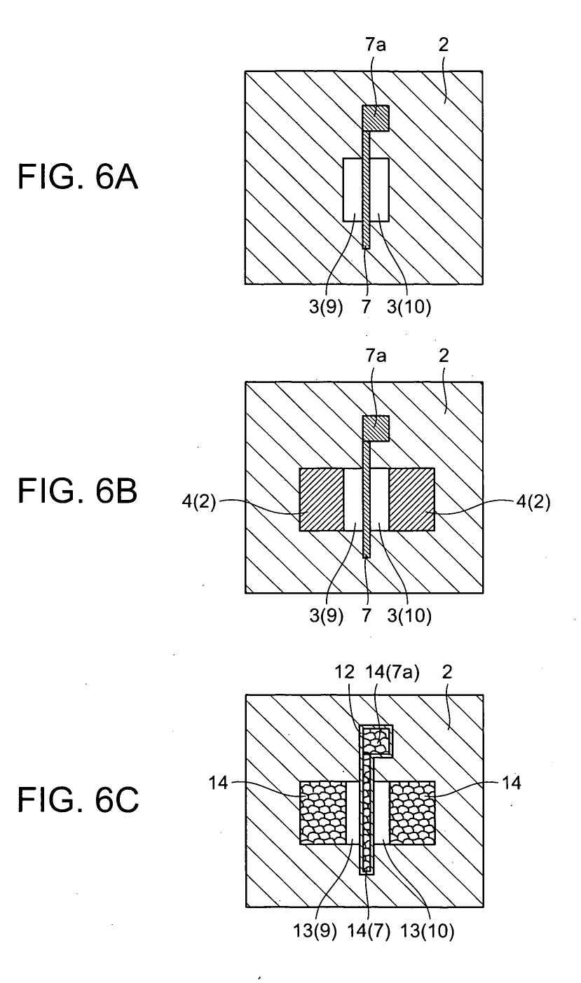

A second embodiment according to the present invention will now be explained using FIGS. 5 and 6.

FIGS. 5A through 5D are process sectional views illustrating the manufacturing processes of a MISFET that is the semiconductor device of the second embodiment.

In FIG. 5A, a gate part forming process will now be explained. The method of forming the LOCOS2 and the MISFET forming region 3 is the same as that in FIG. 1A. In the forming process of the gate part 8, the silicon oxide film is formed as the gate insulating film 6 by a thermal oxidation method after forming the LOCOS2 and the MISFET forming region 3. Then, the polysilicon film that is the gate electrode 7 is formed by a CVD method. Next, the gate electrode 7 and the gate insulating film 6 are processed using a photolithography method and a dry etching method so as to form the gate part 8 in the vicinity of the center of the MISFET forming region 3.

By performing the above-mentioned forming processes of the LOCOS 2, the MISFET forming region 3, and the gate part 8, the following structural body is obtained. That is, the LOCOS 2 and the MISFET forming region 3 are formed on the silicon substrate 1. The gate part 8 that includes the gate insulating film 6 and the gate electrode 7 is formed on the MISFET forming region 3. In this figure, the part of the MISFET forming region 3 that is located at the left side of the gate part 8 is referred to the source part 9, the right side is referred to the drain part 10.

In FIG. 5B, an underlayer film forming process and a pattern forming process of photoresist will now be explained. In the forming process of the silicon nitride film 4 that is the underlayer film, the silicon nitride film 4 is formed on the entire surface of the silicon substrate 1 by the PECVD method. In the pattern forming process of photoresist, the photoresist 5 is patterned by a photolithography method. The pattern of the photoresist 5 is formed such that the photoresist 5 remains only from the border of the MISFET forming region 3 to a part of the LOCOS 2.

The following structural body is obtained by performing the above-mentioned forming process of the silicon nitride film 4 and the pattern forming process of the photoresist. That is, the silicon nitride film 4 is formed on the entire face of the silicon substrate 1 that has been formed as shown in FIG. 5A. The photoresist 5 formed in a pattern is formed on the silicon nitride film 4.

In FIG. 5C, the underlayer film removing process will now be explained.

In the removing process of the silicon nitride film 4 that is the underlayer film, the silicon nitride film 4 is removed by a dry etching method with the photoresist 5 as a mask in the silicon substrate that has been formed as shown in FIG. 5B. Then, the photoresist 5 is removed and the surface of the silicon substrate 1 is cleaned. Subsequently, the extension region 11 is formed by the same way as that in FIG. 1C.

The following structural body is obtained by performing the removing process of the silicon nitride film 4 and the extension region forming process as mentioned above. That is, the gate part 8 that includes the gate insulating film 6 and the gate electrode 7 is formed at nearly (substantially) a center part on the MISFET forming region 3. Also, both sides of the gate part 8 on the element isolation region 2 are the source part 9 and the drain part 10.

The extension region 11 formed by diffusing impurities is formed in the vicinity of the surface of the silicon substrate 1 that becomes the source part 9 and the drain part 10. That is, FIG. 5C shows nearly the same configuration as that in FIG. 1C.

FIG. 5D will now be explained. FIG. 5D shows the same configuration as that in FIG. 1D. That is, the sidewall 12 formed with the insulating film protecting the side face of the gate part 8 is formed. The contact region 15 is formed to the underside of the extension region 11 formed in the silicon substrate 1 of the source part 9 and the drain part 10. Also, the single crystal silicon film 13 is formed on the surface of the silicon substrate 1 of the source part 9 and the drain part 10. Further, the single crystal silicon film 13 is formed on the polysilicon film that is the gate electrode 7.

The polysilicon film 14 is formed on the silicon nitride film 4 formed on the LOCOS 2. The forming methods applied up to FIG. 5D are the same as those applied up to FIG. 1D.

After forming FIG. 5D, the silicide 16 that functions as the conductive film electrically connected to the source part 9 and the drain part 10 is formed on the single crystal silicon film 13 and the polysilicon film 14.

Then, the interlayer insulating film 17, the conductive layer 18 and the electrical wiring 19 are formed to form the MISFET shown in FIG. 2. Therefore, the same effects as those in the first embodiment can be obtained in this embodiment.

FIGS. 6A through C show plan views of the processes of the MISFET formed on the silicon substrate 1. FIG. 6A corresponds to the plan view of FIG. 5A in the process sectional views. FIG. 6B and FIG. 6C correspond to FIG. 5C and FIG. 6D respectively.

FIG. 6A will now be explained. The square like frame shown in the figure represents the surface of the silicon substrate 1 on which the elements are formed and in which the LOCOS 2 and one MISFET forming region 3 are included. In the square like frame, the MISFET forming region 3 is located at the center part and surrounded with the LOCOS 2. The gate part 8, which is represented as an elongated rectangle, is formed from on the LOCOS 2 to the center on the MISFET forming region 3 and further formed on the LOCOS 2. In addition, the contact part 7a for electrical connection is formed at the gate part 8 on the LOCOS 2 located at the upper side in the figure.

Also, in the MISFET forming region 3, one region of both sides of the gate part 8 is the source part 9 and the other region is the drain part 10.

FIG. 6B and FIG. 6C are the same as FIG. 1B and FIG. 1C respectively. Explanations for them will be omitted.

After forming the single crystal silicon film 13 or the polysilicon film 14 shown up to FIG. 6C, the silicide 16 is formed on the source part 9, the drain part 10, the gate electrode 7 and the silicon nitride film 4 formed on the LOCOS 2. This results in the same plan configuration as that in FIG. 4A.

The same effects of the first embodiment described above in (1) through (7) can be obtained in the second embodiment. Further, the following effect can be obtained.

(8) Even if the gate part 8 is first formed, accordingly, the silicon nitride film 4 can be formed on a predetermined region extending from the border of the MISFET forming region 3 to the LOCOS 2 side.

### Third Embodiment

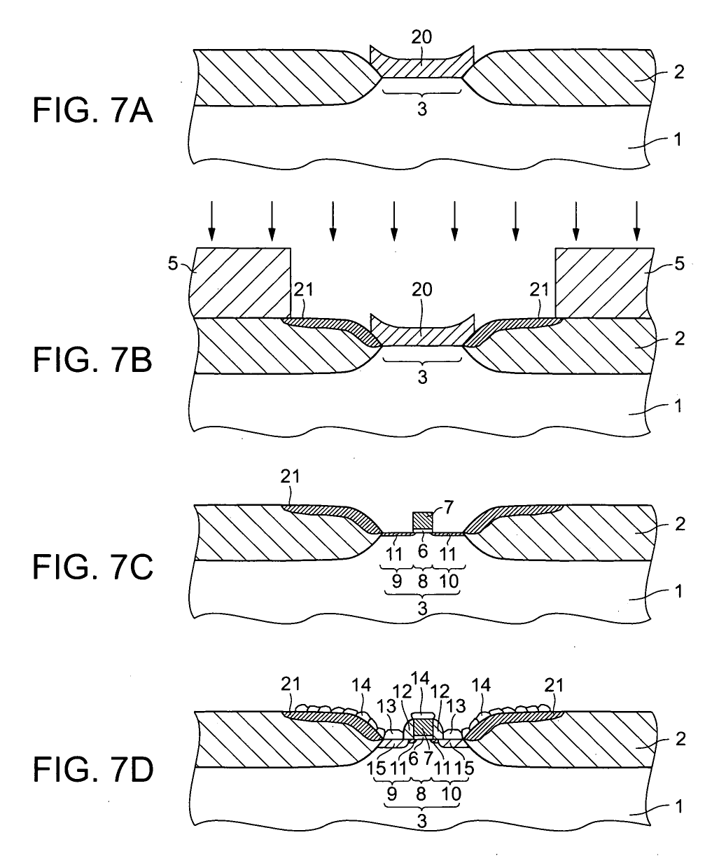

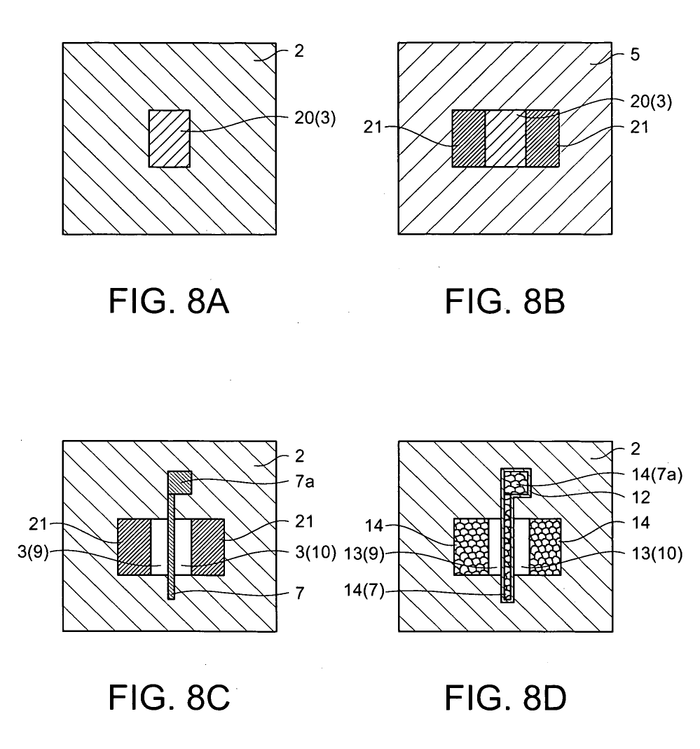

A third embodiment according to the present invention will now be explained using FIGS. 7 and 8.

FIGS. 7A through 7D are process sectional views illustrating the manufacturing processes of a MISFET that is the semiconductor device of the third embodiment.

In FIG. 7A, the forming processes of the LOCOS, the MISFET forming region, and protection film for the MISFET forming region will now be explained. A silicon oxide film (not shown) is formed on the entire face of the silicon substrate 1. Subsequently, a silicon nitride film (not shown) is formed on the silicon oxide film. The silicon nitride film excluding the part becoming the MISFET forming region 3 is removed so as to expose the silicon oxide film of the part becoming the element isolation region 2. Then, the silicon oxide is grown to be thicker by performing thermal oxidation in a thermal oxidation furnace. The silicon oxide film grown thicker becomes the LOCOS 2. The above-mentioned processes are the same as those in FIG. 1(A) of the first embodiment. Here, the silicon nitride film remains on the MISFET forming region 3. The silicon nitride film remains so as to function as a protection film for MISFET forming region 20 without being removed.

The following structural body is obtained by performing the above-mentioned forming processes of the LOCOS 2, the MISFET forming region 3, and the protection film for MISFET forming region. That is, the LOCOS 2 and the MISFET forming region 3 are formed on the silicon substrate 1. The silicon nitride film that is the protection film for MISFET forming region 20 is formed on the MISFET forming region 3.

In FIG. 7B, a resist pattern forming process and a nitrogen ion implantation region forming process will now be explained. In the resist pattern forming process, the photoresist 5 is formed in a pattern on the silicon substrate 1 that has been formed as shown in FIG. 7A. In the nitrogen ion implantation region forming process, nitrogen ions are implanted into the entire face of the silicon substrate 1 by an ion implantation method. In this case, no nitrogen ions are implanted into the part of the LOCOS 2 on which the photoresist 5 is formed, and the part on which the silicon nitride film 20 is formed. The nitrogen ions are implanted into a part of the region extending from the border of the MISFET forming region 3 and onto the LOCOS 2, the region becoming a nitrogen ion implanted region 21.

The following structural body is obtained by performing the above-mentioned resist pattern forming process and the nitrogen ion implantation region forming process. That is, the photoresist 5 formed in a pattern is formed on the silicon substrate 1 that has been formed as shown in FIG. 7A. The photoresist 5 is formed on the LOCOS 2. The photoresist 5 is not formed from the LOCOS 2 to the MISFET forming region 3. In addition, the nitrogen ions are implanted into the entire face of the silicon substrate 1. The nitrogen ion implanted region 21 is formed from the border of the MISFET forming region 3 to a part of the LOCOS 2.

In FIG. 7C, the removing process of the silicon nitride film 20, the forming processes of the gate part 8 and the extension region 11 will now be explained. First, the photoresist 5 formed on the LOCOS 2 is removed by a wet process and an ashing treatment with oxygen plasma. Then, the silicon nitride film 4 formed on the MISFET forming region 3 is removed by an etching method. As for the etching method, a wet process with heated phosphoric acid can be conducted. Etching using a dry etching method also can be conducted. Then, heat treatment is performed so as to remove any damage caused by the ion implantation in the nitrogen ion implantation region 21, and to diffuse the nitrogen ions into the LOCOS 2.

By doing this, at least the surface of the nitrogen ion implanted region 21 becomes near silicon oxynitride. This makes it possible to function as the underlayer film 4 for growing the silicon film or SiGe film in the vapor phase selective epitaxial growth method. If the nitrogen ion implanted region 21 functions as the underlayer film 4 in the epitaxial growth method because of the ion implantation conditions or the like, the heat treatment process is not required. Next, a silicon oxide film is formed on the silicon substrate 1 as the gate insulating film 6. Then, a polysilicon film is formed as the gate electrode 7. Subsequently, the gate part 8 is formed at nearly a center part of the MISFET forming region 3 using a photolithography method and a dry etching method. Then, the extension region 11 is formed in the silicon substrate 1 of the source part 9 and the drain part 10 by ion implantation. This process is the same as that in FIG. 1c.

The following structural body is obtained by performing the removing process of the silicon nitride film 20, the forming processes of the gate part 8 and the extension region 11. That is, the gate part 8 that includes the gate insulating film 6 and the gate electrode 7 is formed on the MISFET forming region 3. The extension region 11 is formed in the source part 9 and the drain part 10. In addition, the nitrogen ion implanted region 21 is formed from the border of the MISFET forming region 3 to a part of the LOCOS 2. At least the surface of the nitrogen ion implanted region 21 becomes near the silicon oxynitride film.

FIG. 7D will now be explained. FIG. 7D shows nearly the same configuration as that in FIG. 1D. The difference is in that the underlayer film 4 of the polysilicon film 14 is the nitrogen ion implanted region 21, not the silicon nitride film. The processing method is the same as that in FIG. 1D. That is, the polysilicon film 14 can be formed on the nitrogen ion implanted region 21 in which the underlayer film 4 becomes the silicon oxynitride film or near silicon oxynitride film by the vapor phase selective epitaxial growth method.

After the formation shown in FIG. 7D, the silicide 16 that functions as the conductive film electrically connected to the source part 9 and the drain part 10 is formed on the single crystal silicon film 13 and the polysilicon film 14. Then, the interlayer insulating film 17, the conductive layer 18 and the electrical wiring 19 are formed so as to form the MISFET shown in FIG. 2. These manufacturing processes are the same as those in FIG. 2.

FIGS. 8A through D show plan views of the processes of the MISFET formed on the silicon substrate 1. FIG. 8A corresponds to the plan view of FIG. 7A in the process sectional views. FIG. 8B, FIG. 8C and FIG. 8D correspond to FIG. 7B, FIG. 7C and FIG. 7D respectively.

FIG. 8A will now be explained. The silicon nitride film is formed on the MISFET forming region 3 as the protection film for MISFET forming region 20, the MISFET forming region 3 being located at the center of the figure and surrounded with the LOCOS 2.

FIG. 8B will now be explained. The nitrogen ion implanted region 21 is formed on the right and the left region on the LOCOS 2, both regions being adjacent to the silicon nitride film 20. The photoresist 5 is formed on the LOCOS 2 surrounding the nitrogen ion implanted region 21 in order to avoid the nitrogen ion implantation.

FIG. 8C will now be explained. The silicon nitride film 20 has been removed. The MISFET forming region 3 is exposed on the surface. The nitrogen ion implanted region 21 is formed on the right and the left region on the LOCOS 2, both regions being adjacent to the silicon nitride film 3.

The gate part 8 is formed from on the LOCOS 2 to the center on the MISFET forming region 3 and further formed on the LOCOS 2. In addition, the contact part 7a for electrical connection is formed at the gate part 8 on the LOCOS 2 located at the upper side in the figure. The photoresist 5 formed on the LOCOS 2 surrounded has been removed.

FIG. 8D will now be explained. The sidewall 12 formed with the silicon oxide is formed to the side face of the gate part 8. The single crystal silicon film 13 is formed on the source part 9 and the drain part 10 in the MISFET forming region 3 by the vapor phase selective epitaxial method. In addition, the polysilicon film 14 is formed on the gate electrode 7 and on the nitrogen ion implanted region 21 that is formed in the LOCOS 2.

After FIG. 8D, the suicide 16 is formed on the source part 9, the drain part 10, the gate electrode 7 and the silicon nitride film 4 formed on the LOCOS 2. This results in the same plan configuration as that in FIG. 4A.

The same effects of the first embodiment described above in (1) through (7) can be obtained in the third embodiment. Further, the following effect can be obtained.

(9) The photoresist 5 is opened by a photolithography method at a desired region of the LOCOS 2, the desired region being a part of the LOCOS 2, and the MISFET forming region 3 on the silicon substrate 1 in which the silicon nitride film 20 is formed on the LOCOS 2 and the MISFET forming region 3. The nitrogen ion implanted region 21 can be formed on a desired region extending from the border of the MISFET forming region 3 to the LOCOS 2 side by performing the nitrogen ion implantation on the entire face of the silicon substrate 1. Then, the single crystal silicon film 13 or the polysilicon film 14 or the mixed crystal film 24 of single crystal silicon and germanium or the mixed crystal film 25 of polysilicon and germanium can be selectively formed only on the MISFET forming region 3 and the nitrogen ion implanted region 21 by the vapor phase selective epitaxial growth method.

### Fourth Embodiment

A problem associated with the micro miniaturization of MISFET elements arises in which characteristics of the MISFET elements are deteriorated by depletion at the gate part 8 in the case where the gate electrode 7 is formed with the polysilicon, Therefore, the gate electrode 7 may be formed with metal such as tantalum (Ta), not polysilicon. In the case where the gate electrode is formed with metal, the depletion at the gate part 8 does not have much influence on the characteristics of the MISFET elements.

However, if the gate electrode 7 is formed with metal, a high temperature process cannot be used in succeeding processes. Thus, the film forming temperature in the vapor phase selective epitaxial method in the above-mentioned embodiments 1 through 3 is 600 degrees centigrade or less. If the film forming temperature is 600 degrees centigrade or less, the film growth speed of the single crystal silicon film 13 and the polysilicon film 14 becomes slow. This brings throughput down in this process. If the single crystal SiGe film 24 and the polycrystal SiGe film 25, both having a high film growth speed, are intended to be formed, another problem arises. That is, the SiGe film cannot be evenly formed because of abnormal growth, if there are impurities, for example, such as carbon, in the lower layer on which the film is grown. In contrast, the silicon film can be evenly formed without much influence of the impurities in the underlayer film while the film growth speed is slow as mentioned above.

In consideration of both advantages, in this embodiment, the film for forming the silicide 16 has a double-layer structure of silicon film and SiGe film as shown below. That is, influences of impurities on the surface of the silicon substrate 1 or in the underlayer film 4 are reduced by forming the silicon film. The throughput down in the vapor phase selective epitaxial growth process is avoided by forming the SiGe film on the formed silicon film.

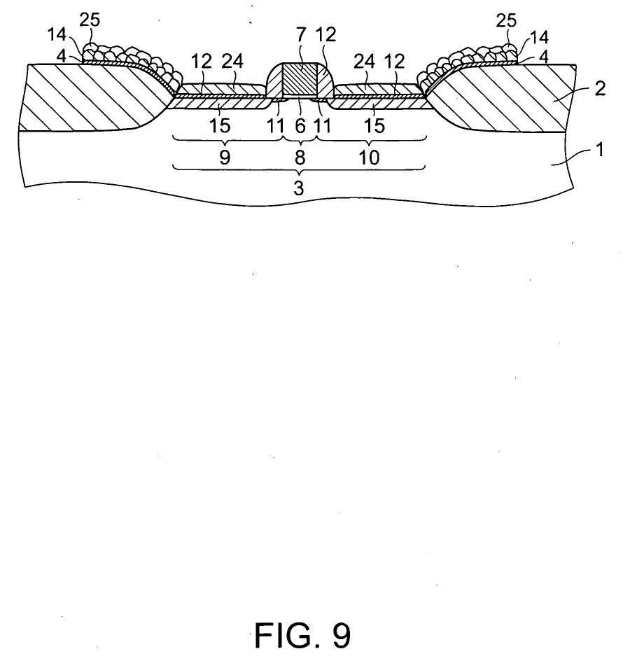

FIG. 9 will now be explained. The forming processes up to FIG. 9 are the same as those in FIG. 1A through 1C of the first embodiment, FIG. 5A through 5C of the second embodiment, and FIG. 7A through C of the third embodiment. FIG. 7C differs from FIG. 1C and FIG. 5C in that the silicon nitride film 4 is replaced to the nitrogen ion implanted region 21. Since the silicon nitride film 4 and the nitrogen ion implanted region 21 functions as the underlayer film for forming film in the vapor phase selective epitaxial growth method, hereinafter, the case where the forming processes up to FIG. 9 has been performed by the first embodiment in which the silicon nitride 4 is formed will be explained as a representative example.

After forming the sidewall 12, the single crystal silicon film 13, the polysilicon film 14, the single crystal SiGe film 24 and the polycrystal SiGe film 25 are formed by the vapor phase selective epitaxial growth method.

First, impurities such as organic materials or metals or the like on the silicon substrate 1 are removed by performing a wet process to the silicon substrate 1 in which the sidewall 12 has been formed. The wet process may be performed several times depending on the surface conditions or the like of the silicon substrate 1. Several kinds of acid cleanings or the like may be conducted. Next, the silicon substrate 1 is put into a vapor phase epitaxial growth furnace so as to form the single crystal film 13 on the source part 9 and the drain part 10, and the polysilicon film 14 on the silicon nitride film 4 on the LOCOS 2. Next, the single crystal SiGe film 24 is formed on the single crystal silicon film 13. The polycrystal SiGe film 25 is formed on the polysilicon film 14.

The vapor phase selective epitaxial growth method in the embodiment will now be precisely explained. In the silicon film forming process, the single crystal silicon film 13 and the polysilicon film 14 are formed. The silicon films 13 and 14 are formed by the vapor phase epitaxial growth method at a temperature range from 500 degrees centigrade to 600 degrees centigrade by only supplying disilane (hereinafter referred to Si₂H₆) gas. In this case, the silicon films 13 and 14 are formed to a film thickness of approximately 5 nm. In addition, the silicon films 13 and 14 are formed by the selective epitaxial growth method by which the films are formed only on the part of the silicon substrate 1 where the silicon surface is exposed. The silicon films 13 and 14 are not formed on the element isolation region 2 formed with thick silicon oxide film, the gate electrode 7 formed with metal and the sidewall 12. Here, the silicon films 13 and 14 can be grown, even though the impurities are on the surface of the silicon substrate 1. Also, they play a role such that the SiGe films 24 and 25 that are formed later are not influenced by the impurities of the silicon substrate 1.

Here, it is preferable that the formed film thickness of the silicon films 13 and 14 are 1 nm or more and 10 nm or less. More preferably, 3 nm or more and 8 nm or less, further preferably, 4 nm or more and 6 nm or less. If the film thickness of the silicon films 13 and 14 are thin, 1 nm or less, impurities such as carbon or the like on the substrate surface cannot be kept in the silicon films 13 and 14, adversely affecting the formation of the SiGe films 24 and 25. Also, if the film thickness of the silicon films 13 and 14 are formed to 10 nm or more, the throughput of this process is deteriorated. This is because it takes a long time until a desired film thickness is formed due to the low film growth rate of the silicon films 13 and 14.

The forming process of the SiGe films 24 and 25 include two processes, a mixed gas supply process and a halogen gas supply process. In the mixed gas supply process, the SiGe films 24 and 25 are formed. The SiGe films 24 and 25 are formed by the vapor phase selective epitaxial growth method like the silicon films 13 and 14. After forming the silicon films 13 and 14 at a desired thickness, Si₂H₆ gas and GeH₄ gas are supplied at a predetermined flow ratio at a temperature range from 500 degrees centigrade to 600 degrees centigrade. In this case, the SiGe films 24 and 25 are formed to a film thickness of approximately 50 nm. Here, the SiGe films 24 and 25 are grown only on the silicon films 13 and 14 formed, not formed on the element isolation region 2, the gate electrode 7 and the sidewall 12. If the SiGe films 24 and 25 are intended to be formed without forming the silicon films 13 and 14, the film-forming processes becomes unstable, for example, the film is not formed due to the influence of impurities on the silicon substrate 1 etc., the film is grown in isolation, and the film growth rate is slow etc. Therefore, the formation of the silicon films 13 and 14 in the silicon film forming process is important to stabilize the film forming processes.

Here, it is preferable that the formed film thickness of the SiGe films 24 and 25 are 10 nm or more and 100 nm or less. More preferably, 20 nm or and more 80 nm or less, further preferably, 30 nm or more and 70 nm or less.

If the film thickness of the SiGe films 24 and 25 are 10 nm or less, there is a possibility to arise a problem in forming the silicide 16. That is, if the silicide 16 is formed, there is a possibility that the silicide 16 reaches to the surface of the silicon substrate 1 or formed deeper through the surface depending on the temperature and time in the heat treatment conditions. If the suicide 16 reaches the silicon substrate 1, a problem of a junction leakage due to the silicide 16 arises. In addition, in the case where the film thickness of the single crystal SiGe film 24 is thick, 100 nm or more, there is a possibility that the film crosses over the sidewall 12 to be shorted to the gate electrode 7 if it is too thick. Further, it is not preferable that the film is formed needlessly thick because it slows the throughput in the processes or increases raw material consumption.

In the halogen gas supply process, chlorine (hereinafter referred to as Cl₂) gas is supplied. After stopping the supply of Si₂H₆ gas and GeH₄ gas that are the raw gas for the SiGe films 24 and 25, Cl₂ gas is supplied at the same temperature as that in the vapor phase selective epitaxial growth.

If the mixed gas supply process is performed after supplying the Cl₂ gas in the halogen gas supply process, the SiGe films 24 and 25 can be formed again with Si₂H₆ gas and GeH₄ gas that are supplied in the mixed gas supply process.

Processes after forming the silicon films 13 and 14, and the SiGe films 24 and 25 are the same as those in embodiments 1 through 3. However, since the gate electrode 7 is metal such as Ta or the like, a low temperature process can be conducted. Thus, nickel is used as the metal of the silicide 16. The reason is that the nickel silicide 16 can be formed at a low temperature of approximately 500 degrees centigrade.

The same effects of the first embodiment described above in (1) through (7) can be obtained in the fourth embodiment. Further, the following effect can be obtained.

(10) The silicon films 13 and 14, and the SiGe films 24 and 25 that become the silicide 16 as the conductive layer, can be formed by the process at 600 degrees centigrade or less even though the gate electrode 7 is formed with metal such as Ta or the like.

Modification

The invention is not limited to the above-mentioned embodiments. At least the following modifications can be applicable.

First Modification

The single crystal silicon film 13, the polysilicon film 14, and the SiGe films 24 and 25 that are formed by the vapor phase selective epitaxial growth method are not limited to non-doped films. Phosphorus (P), arsenic (As), and boron (B), etc., can be included.

Second Modification

The semiconductor substrate 1 is not limited to the silicon substrate. Compound semiconductors such as gallium arsenide (GaAs), indium phosphorus (InP), and gallium nitride (GaN), etc., can be used.

Third Modification

The material for forming the silicide is not limited to Ti. Metal such as Cobalt (Co), nickel (Ni), platinum (Pt), etc., can be used.

Fourth Modification

The material for the conductive layer is not limited W, aluminum (Al) and copper (Cu) can be used.

Fifth Modification

The gate electrode can be formed with metallic materials such as tantalum (Ta), and tantalum nitride (TaN), etc., in addition to the polysilicon. In this case, the polysilicon film 14 or the polycrystal SiGe film 25 that is formed by the vapor phase selective growth method is not formed on the gate electrode. However, this causes no problem in the invention because the gate electrode itself is metal (a low resistance material).

Sixth Modification

The single crystal silicon film 13 or the polysilicon film 14 may be formed using any one type of gas of SiH₄, SiH₂Cl₂, SiHCl₃, SiCl₄, SiF₄, or organic silane type gases in addition to Si₂H₆.

Seventh Modification

The single crystal SiGe film 24 or the polycrystal SiGe film 25 may be formed by supplying the mixed gas of GeH₄ and SiH₄, SiH₂Cl₂, SiHCl₃, SiCl₄, SiF₄, or organic silane type gases in addition to Si₂H₆.

Technical ideas derived from the embodiments will be described below with the effects.

(1) The method of manufacturing a semiconductor device provided with a semiconductor substrate on which the element isolation region and the active element forming region are formed includes the underlayer forming process forming the silicon nitride film or the silicon oxynitride film on the entire face of the semiconductor substrate, the underlayer removing process leaving the silicon nitride film or the silicon oxynitride film as the underlayer film in a predetermined region which extends from a border of the active element forming region to the element isolation region side as well as removing the rest of the underlayer film except the predetermined region, the gate part forming process forming the gate part including the gate insulating film and the gate electrode to the active element forming region, the contact region forming process forming the contact region of the source part and the drain part to the active element forming region by ion implantation, and the vapor phase selective epitaxial process forming the sidewall made of the insulating film to the side face of the gate part and forming the single crystal silicon or the single crystal that is made of mixed crystal of silicon and germanium to the source part and the drain part, and the polysilicon or the polycrystal that is made of mixed crystal of silicon and germanium on the upper part of the gate electrode and on the silicon nitride film or the silicon oxynitride film by a vapor phase selective epitaxial growth method.

According to the method, the silicon nitride film or the silicon oxynitride film can be formed to the predetermined region extending from the border of the active element forming region to the element isolation region side. Then, the silicon film or the mixed crystal film of silicon and germanium can be selectively formed only to the active element forming region and the region to which the silicon nitride film or the silicon oxynitride film is formed by the vapor phase selective epitaxial growth method. In addition, if the gate electrode is formed with the polysilicon, the polysilicon film or the polycrystal film that is made of mixed crystal of silicon and germanium can be selectively formed on the gate electrode by the epitaxial growth method. The silicon or the mixed crystal of silicon and germanium can readily be turned into the conductive film, for example, by making it to be the silicide. Since the conductive film can be electrically connected to the active element, the electrical connection to the electrical wiring can be conducted in the element isolation region, not the active element forming region. This makes it possible to reduce the area of the source/drain, for example, in the MIS field effect transistor.

(2) The method of manufacturing a semiconductor device provided with a semiconductor substrate on which the element isolation region and the active element forming region are formed includes the gate part forming process forming the gate part including the gate insulating film and the gate electrode to the active element forming region, the process forming the silicon nitride film or the silicon oxynitride to the entire face of the semiconductor substrate, the underlayer removing process leaving the silicon nitride film or the silicon oxynitride film as the underlayer film in a predetermined region which extends from a border of the active element forming region to the element isolation region side as well as removing the rest of the underlayer film except the predetermined region by an etching, the contact region forming process forming the contact region of the source part and the drain part to the active element forming region by ion implantation, and the vapor phase selective epitaxial process forming the sidewall made of the insulating film to the side face of the gate part and forming the single crystal silicon or the single crystal that is made of mixed crystal of silicon and germanium to the source part and the drain part, and the polysilicon or the polycrystal that is made of mixed crystal of silicon and germanium on the upper part of the gate electrode and on the silicon nitride film or the silicon oxynitride film by a vapor phase selective epitaxial growth method.

According to the method, even if the gate part is first formed, accordingly, the silicon nitride film or the silicon oxynitride film can be formed to the predetermined region extending from the border of the active element forming region to the element isolation region side. In addition, if the gate electrode is formed with the polysilicon, the polysilicon film or the polycrystal film that is made of mixed crystal of silicon and germanium can be selectively formed on the gate electrode by the epitaxial growth method. Therefore, the same effects as those mentioned above can be obtained.

(3) The method of manufacturing a semiconductor device provided with a semiconductor substrate in which the silicon nitride film is formed on the element isolation region and the active element forming region includes the resist pattern forming process removing photoresist formed on the desired region of the element isolation region and the active element forming region to be the opening, the nitrogen ion implanted region forming process implanting nitrogen ions into the entire face of the semiconductor substrate so as to form the nitrogen ion implanted region to the element isolation region in the opening, the silicon nitride film removing process removing the photoresist film and the silicon nitride film, the gate part forming process forming the gate part including the gate insulating film and the gate electrode to the active element forming region, the contact region forming process forming the contact region of the source part and the drain part to a transistor forming region by ion implantation, and the vapor phase selective epitaxial process forming the sidewall made of the insulating film to the side face of the gate part and forming the single crystal silicon or the single crystal that is made of mixed crystal of silicon and germanium to the source part and the drain part, and the polysilicon or the polycrystal that is made of mixed crystal of silicon and germanium on the upper part of the gate electrode and to the nitrogen ion implanted region by a vapor phase selective epitaxial growth method.

According to the method, the nitrogen ion implanted region can be formed to the predetermined region extending from the border of the active element forming region to the element isolation region side in the following way. In the semiconductor substrate in which the silicon nitride film is formed on the element isolation region and the active element forming region, the photoresist film that is formed on a desired region of the element isolation region and the transistor forming region is removed to be the opening by the photolithography method. Then, nitrogen ions are implanted into the entire face of the semiconductor substrate. Next, the silicon film or the mixed crystal film of silicon and germanium can be selectively formed only to the active element forming region and the nitrogen ion implanted region by the vapor phase selective epitaxial growth method. In addition, if the gate electrode is formed with the polysilicon, the polysilicon film or the polycrystal film that is made of mixed crystal of silicon and germanium can be selectively formed on the gate electrode by the epitaxial growth method. Therefore, the same effects as those mentioned above can be obtained.

(4) The method of manufacturing a semiconductor device provided with a semiconductor substrate in which the silicon nitride film is formed on the element isolation region and the active element forming region includes the resist pattern forming process removing photoresist formed on the desired region of the element isolation region and the silicon nitride film to be the opening by a photolithography method, the nitrogen ion implanted region forming process implanting nitrogen ions into the entire face of the semiconductor substrate so as to form the nitrogen ion implanted region to the element isolation region in the opening, the heat treatment process performing the heat treatment to the semiconductor substrate, the silicon nitride film removing process removing the photoresist film and the silicon nitride film, the gate part forming process forming the gate part including the gate insulating film and the gate electrode to the active element forming region, the contact region forming process forming the contact region of the source part and the drain part to a transistor forming region by ion implantation, and the vapor phase selective epitaxial process forming the sidewall made of the insulating film to the side face of the gate part and forming the single crystal silicon film or the single crystal film that is made of mixed crystal of silicon and germanium to the source part and the drain part by a vapor phase selective epitaxial growth method and the polysilicon film or the polycrystal film that is made of mixed crystal of silicon and germanium to the nitrogen ion implanted region.

According to the method, the nitrogen ion implanted region can be formed to the predetermined region extending from the border of the active element forming region to the element isolation region side in the following way. In the semiconductor substrate in which the silicon nitride film is formed on the element isolation region and the active element forming region, the photoresist film that is formed on a desired region of the element isolation region and the silicon nitride film is removed to be the opening by the photolithography method. Then, nitrogen ions are implanted into the entire face of the semiconductor substrate. In addition, damage in the nitrogen ion implanted region can be recovered by performing the heat treatment after implanting nitrogen ions. Also, the nitrogen ion implanted region can be stabilized by diffusing nitrogen ions in the semiconductor substrate. Next, the silicon film or the mixed crystal film of silicon and germanium can be selectively formed only to the active element forming region and the nitrogen ion implanted region by the vapor phase selective epitaxial growth method. Therefore, the same effects as those mentioned above can be obtained.

(5) The semiconductor device provides a semiconductor substrate including the active element forming region forming the active element, the element isolation region isolating the element, the underlayer film formed on the predetermined region on the element isolation region, the predetermined region extending from the border of the active element forming region to the element isolation region side, and the conductive film formed on the active element forming region and the underlayer film.

According to the configuration, by forming the underlayer film including nitrogen on the predetermined region on the element isolation region, the predetermined region extending from the border of the active element forming region to the element isolation region side, the silicon or the mixed crystal of silicon or germanium can readily and selectively be formed on the underlayer film. The silicon or the mixed crystal of silicon and germanium can readily be turned into the conductive film, for example, by making it to be the silicide. Since the conductive film can be electrically connected to the active element, the electrical connection to the electrical wiring can be conducted in the element isolation region, not the active element forming region. This makes it possible to reduce the area of the source part and the drain part, for example, in the MIS field effect transistor. The reduction of the area of the source part and the drain part has an effect of reducing parasitic capacitance. Further, since the contact of the source part and the drain part can be located on the LOCOS, there is an effect of widening the layout design freedom.

1. A semiconductor device provided with a semiconductor substrate, comprising:
an active element forming region for forming active elements;
an element isolation region for isolating one element from another element;
an underlayer film including nitrogen formed on a predetermined region on the element isolation region, the predetermined region extending from a border of the active element forming region to the element isolation region side; and
a conductive film formed on the active element forming region and the underlayer film.

2. The semiconductor device according to claim 1, wherein:
the conductive film includes a silicide and the underlayer film comprises one of a silicon nitride film and a silicon oxynitride film.

3. The semiconductor device according to claim 1 further comprising:
an interlayer insulating film formed on the semiconductor substrate;
an electrical wiring formed on the interlayer insulating film; and
a conductive layer formed so as to penetrate the interlayer insulating film to electrically couple the conductive film formed on the element isolation region to the electrical wiring.

4. The semiconductor device according to claim 1 further comprising:
a gate part including a gate insulating film and a gate electrode that are formed to the active element forming region; and
a conductive film formed on the element isolation region that is located at both sides of the gate part, the conductive film being patterned so as to exclude a lower layer of the gate insulating film,
wherein the active element formed to the active element forming region comprises a MISFET.

5. A method of manufacturing a semiconductor device provided with a semiconductor substrate on which an element isolation region and an active element forming region are formed, the method comprising:
forming one of a silicon nitride film and a silicon oxynitride film as an underlayer film on an entire surface of the semiconductor substrate;
removing the underlayer film except in a predetermined region which extends from a border of the active element forming region to the element isolation region side; and
forming a gate part including a gate insulating film and a gate electrode to the active element forming region;
forming a contact region of a source part and a drain part to the active element forming region by ion implantation;
forming a sidewall made of an insulating film to a side face of the gate part; and
performing a vapor phase selective epitaxial growth including:
forming one of a single crystal silicon film and a single crystal film made of mixed crystal of silicon and germanium to the source part and the drain part; and
forming one of a polysilicon film and a polycrystal film made of the mixed crystal of silicon and germanium on the one of the silicon nitride film and the silicon oxynitride film.

6. A method of manufacturing a semiconductor device provided with a semiconductor substrate on which an element isolation region and an active element forming region are formed, the method comprising:
forming a gate part including a gate insulating film and a gate electrode to the active element forming region;
forming one of a silicon nitride film and a silicon oxynitride film as an underlayer film on an entire surface of the semiconductor substrate;
removing the underlayer film except in a predetermined region which extends from a border of the active element forming region to the element isolation region side;
forming a contact region of a source part and a drain part to the active element forming region by ion implantation;
forming a sidewall made of an insulating film to a side face of the gate part; and
performing a vapor phase selective epitaxial growth including:
forming one of a single crystal silicon film and a single crystal film made of mixed crystal of silicon and germanium to the source part and the drain part; and
forming one of a polysilicon film and a polycrystal film made of the mixed crystal of silicon and germanium on the one of silicon nitride film and the silicon oxynitride film.

7. A method of manufacturing a semiconductor device provided with a semiconductor substrate in which a silicon nitride film is formed on an element isolation region and an active element forming region, the method comprising:
removing photoresist formed on a desired region on the element isolation region and the silicon nitride film to form an opening by a photolithography method;
implanting a nitrogen ion into an entire surface of the semiconductor substrate so as to form a nitrogen ion implanted region to the element isolation region in the opening;
removing the photoresist and the silicon nitride film;
forming a gate part including a gate insulating film and a gate electrode to the active element forming region;
forming a contact region of a source part and a drain part to the active element forming region by ion implantation;
forming a sidewall to a side face of the gate part; and
performing a vapor phase selective epitaxial growth including:
forming one of a single crystal silicon film and a single crystal film made of mixed crystal of silicon and germanium to the source part and the drain part; and
forming one of a polysilicon film and a polycrystal film made of the mixed crystal of silicon and germanium on the nitrogen ion implanted region.

8. A method of manufacturing a semiconductor device provided with a semiconductor substrate on which an element isolation region and an active element forming region are formed, the method comprising:
forming one of a silicon nitride film and a silicon oxynitride film as an underlayer film on an entire surface of the semiconductor substrate;
removing the underlayer film except in a predetermined region which extends from a border of the active element forming region to the element isolation region side;
forming a gate part including a gate insulating film and a gate electrode made of a metal element to the active element forming region;
forming a contact region of a source part and a drain part to the active element forming region by ion implantation;
forming a sidewall made of an insulating film to a side face of the gate part;
performing a vapor phase selective epitaxial growth in a range of 500 degrees centigrade or more to 600 degrees centigrade or less, the vapor phase selective epitaxial growth including:
forming single crystal silicon to the source part and the drain part; and
forming polysilicon on the one of the silicon nitride film and the silicon oxynitride film; and
performing a vapor phase selective epitaxial growth in a range of 500 degrees centigrade or more to 600 degrees centigrade or less, the vapor phase selective epitaxial growth including:
forming a single crystal film made of mixed crystal of silicon and germanium on the single crystal silicon film; and
forming a polycrystal film made of mixed crystal of silicon and germanium on the polysilicon film.

9. A method of manufacturing a semiconductor device provided with a semiconductor substrate on which an element isolation region and an active element forming region are formed, the method comprising:
forming a gate part including a gate insulating film and a gate electrode made of a metal element to the active element forming region;
forming one of a silicon nitride film and a silicon oxynitride film as an underlayer film on an entire surface of the semiconductor substrate;
removing the underlayer film except in a predetermined region which extends from a border of the active element forming region to the element isolation region side;
forming a contact region of a source part and a drain part to the active element forming region by ion implantation;
forming a sidewall made of an insulating film to a side face of the gate part;
performing a vapor phase selective epitaxial growth at a range of 500 degrees centigrade or more to 600 degrees centigrade or less, the vapor phase selective epitaxial growth including:
forming single crystal silicon to the source part and the drain part; and
forming polysilicon on the one of the silicon nitride film and the silicon oxynitride film; and
performing a vapor phase selective epitaxial growth at a range of 500 degrees centigrade or more to 600 degrees centigrade or less, the vapor phase selective epitaxial growth including:
forming a single crystal film made of mixed crystal of silicon and germanium on the single crystal silicon film; and
forming a polycrystal film made of the mixed crystal of silicon and germanium on the polysilicon film.

10. A method of manufacturing a semiconductor device provided with a semiconductor substrate in which a silicon nitride film is formed on an element isolation region and an active element forming region, the method comprising:
removing photoresist formed on a desired region of the element isolation region and the silicon nitride film to form an opening by a photolithography method;
implanting a nitrogen ion into an entire surface of the semiconductor substrate so as to form a nitrogen ion implanted region to the element isolation region in the opening;
removing the photoresist and the silicon nitride film;
forming a gate part including a gate insulating film and a gate electrode made of a metal element to the active element forming region;
forming a contact region of a source part and a drain part to the active element forming region by ion implantation;
forming a sidewall to a side face of the gate part;
performing a vapor phase selective epitaxial growth at a range of 500 degrees centigrade or more to 600 degrees centigrade or less, the vapor phase selective epitaxial growth including:
forming single crystal silicon to the source part and the drain part; and
forming polysilicon on one of the silicon nitride film and the silicon oxynitride film; and
performing a vapor phase selective epitaxial growth at a range of 500 degrees centigrade or more to 600 degrees centigrade or less, the vapor phase selective epitaxial growth including:
forming a single crystal film made of mixed crystal of silicon and germanium on the single crystal silicon film; and
forming a polycrystal film made of the mixed crystal of silicon and germanium on the polysilicon film.

11. The method of manufacturing a semiconductor device according to claim 5, wherein:
the gate insulating film and the underlayer film are formed so as to be prevented from overlapping in at least one of the step of forming the gate part and the step of forming the underlayer film.

12. The method of manufacturing a semiconductor device according to claim 5 further comprising:
forming a metal film to an entire surface of the semiconductor substrate;
performing a heat treatment to the semiconductor substrate so as to form a silicide; and
removing an excess metal film that is not turned into the suicide on the semiconductor substrate,
wherein the steps of forming the metal film, performing the heat treatment and removing the excess metal film are conducted after the steps of forming the sidewall and performing the vapor phase selective growth.

13. The manufacturing method of a semiconductor device according to claim 12 further comprising:
forming an interlayer insulating film on the semiconductor substrate;
forming an opening to the interlayer insulating film on the silicide formed on the element isolation region;
plugging a conductive member into the opening so as to form a conductive layer;
forming an electrical wiring film on the interlayer insulating film; and
forming an electrical wiring by patterning the electrical wiring film.
